(19) United States
(12) Patent Application Publication
(10) Pub. No.: US 2022/0123004 A1
(43) Pub. Date: Apr. 21, 2022

(54) THREE-DIMENSIONAL NAND MEMORY DEVICE WITH SPLIT CHANNEL GATES

(71) Applicant: Yangtze Memory Technologies Co., Ltd., Wuhan (CN)

(72) Inventors: Xiaoxin LIU, Wuhan (CN); Lei XUE, Wuhan (CN); Jiaqian XUE, Wuhan (CN); Wanbo GENG, Wuhan (CN); Tingting GAO, Wuhan (CN)

(73) Assignee: Yangtze Memory Technologies Co., Ltd., Wuhan (CN)

(21) Appl. No.: 17/128,618

(22) Filed: Dec. 21, 2020

Related U.S. Application Data
(63) Continuation of application No. PCT/CN2020/121809, filed on Oct. 19, 2020.

(51) Int. Cl. H01L 27/11556; H01L 27/11582; H01L 27/11519; H01L 27/11565; H01L 27/1157; H01L 27/11524; G11C 8/14

(52) U.S. Cl. CPC H01L 27/11556; H01L 27/11582; H01L 27/11519; G11C 8/14; H01L 27/1157; H01L 27/11524; H01L 27/11565

(57) ABSTRACT

A semiconductor device is provided. The semiconductor device includes word line layers and insulating layers that are alternatingly stacked along a vertical direction perpendicular to a substrate of the semiconductor device. A first channel structure of the semiconductor device extends along a first vertical axis in the vertical direction through the word line layers and the insulating layers. The first channel structure includes a plurality of storage structures and a first isolation structure. The storage structures are arranged around the first isolation structure. The first isolation structure extends along the first vertical axis and separates the storage structures from one another.

### RELATED APPLICATION

This application is a bypass continuation of International Application No. PCT/CN2020/121809, filed on Oct. 19, 2020. The entire disclosure of the prior application is hereby incorporated by reference in its entirety.

### BACKGROUND

Flash memory devices have recently been through a rapid development. The flash memory devices are able to retain the stored data for a long period of time without applying a voltage. Further, the reading rate of the flash memory devices is relatively high, and it is easy to erase stored data and rewrite data into the flash memory devices. Thus, the flash memory devices have been widely used in micro-computers, automatic control systems, and the like. To increase the bit density and reduce the bit cost of the flash memory devices, three-dimensional (3D) NAND (Not AND) flash memory devices have been developed.

In recent years, as the cell layers of the 3D-NAND exceeds 100 layers, it is increasingly challenging to manage trade-offs among an etch profile control, a size uniformity and a productivity. For example, as the bit density of the 3D-NAND memory device increases, the alignment issue of the channel holes in different stacks (e.g., an upper stack and a lower stack) or the connection issue of the high dense channel holes based on a double pattern is getting worse.

### SUMMARY

In the present disclosure, embodiments directed to a 3D-NAND memory device with split channel gates and a method of manufacturing the same are provided.

According to an aspect of the present disclosure, a semiconductor device is provided. The semiconductor device can include word line layers and insulating layers that are alternatingly stacked along a vertical direction perpendicular to a substrate of the semiconductor device. A first channel structure of the semiconductor device can extend along a first vertical axis in the vertical direction through the word line layers and the insulating layers. The first channel structure can include a plurality of storage structures and a first isolation structure. The storage structures can be arranged around the first isolation structure. The first isolation structure can separate the storage structures from one another.

In some embodiments, the storage structures can include three storage structures that are equally spaced apart from one another around the first isolation structure.

In another embodiment, the storage structures can include three storage structures that are unequally spaced apart from one another around the first isolation structure.

In some embodiments, the first isolation structure and the three storage structures can be concentrically arranged along the first vertical axis. Thus, a first angular distance between a first storage structure and a second storage structure of the three storage structures in a cross-section of the first channel structure, a second angular distance between the first storage structure and a third storage structure of the three storage structures in the cross-section of the first channel structure, and a third angular distance between the second storage structure and the third storage structure of the three storage structures in the cross-section of the first channel structure can be equal.

In the semiconductor device, a cross-section of the first isolation structure that is perpendicular to the first vertical axis can have a circular profile or an oval profile. Further, a first storage structure of the storage structures can include a barrier layer, a charge trapping layer, a tunneling layer, and a channel layer that are concentrically arranged along the first vertical axis in the first channel structure. In addition, the barrier layer can be formed along the vertical direction and in contact with the word line layers and the insulating layers. The charge trapping layer can be formed over an inner surface of the barrier layer and extend in the vertical direction. The tunneling layer can be formed over an inner surface of the charge trapping layer and extend in the vertical direction. The channel layer can be formed over an inner surface of the tunneling layer and extend in the vertical direction.

In an exemplary embodiment, the cross-section of the first isolation structure can have a circular shape with a radius equal to R. The radius can be centered at an interception point between the cross-section of the first channel structure and the first vertical axis, and the R can be in a range of 20 nm to 50 nm.

In the semiconductor device, a cross-section of the first storage structure of the three storage structures that is perpendicular to the first vertical axis can include a top side and two opposing edge sides. A first distance between the first vertical axis and the top side can be equal to 2R that is in a range of 70 nm to 100 nm. A second distance between the two opposing edge sides can be equal to \sqrt{3} R that is in a range of 50 nm to 80 nm. A critical dimension of the cross-section of the first channel structure can be equal to 5\sqrt{3}/2R that is in a range of 130 nm to 170 nm.

The semiconductor device can include a second channel structure. The second channel structure can extend along a second vertical axis in the vertical direction and include a plurality of storage structures and a second isolation structure. The storage structures can extend away from the second vertical axis and are concentrically arranged along the second vertical axis. The second isolation structure can be positioned in the second channel structure so as to extend along the second vertical axis and separate the storage structures of the second channel structure from one another. In some embodiments, the second channel structure can be positioned at a first side of the first channel structure and have an opposing orientation to an orientation of the first channel structure. A space between the first channel structure and the second channel structure can be in a range of 40 nm to 60 nm.

The semiconductor device can further include a third channel structure. The third channel structure can extend along a third vertical axis in the vertical direction and include a plurality of storage structures and a third isolation structure. The storage structures can extend away from the third vertical axis and concentrically arranged along the third vertical axis. The third isolation structure can be positioned in the third channel structure so as to extend along the third vertical axis and separate the storage structures of the third channel structure from one another. The third channel structure can be positioned at a second side of the first channel structure and have a same orientation to the orientation of the first channel structure. A space between the first channel structure and the third channel structure can be in a range of 50 nm to 70 nm.

According to another aspect of the disclosure, a method for forming a semiconductor is provided. In the method, a stack that includes word line layers and insulating layers can be formed. The word line layers and the insulating layers can be arranged alternatingly along a vertical direction perpendicular to a substrate. A first channel structure can be formed in the stack. The first channel structure can extend along a first vertical axis in the vertical direction through the word line layers and the insulating layers. The first channel structure can include a plurality of storage structures that extend away from the first vertical axis and are arranged concentrically along the first vertical axis. A first isolation structure can be subsequently formed, where the first isolation structure can be arranged in the first channel structure so as to extend along the first vertical axis and separate the storage structures from one another.

In some embodiments, in order to form the first channel structure, a channel hole can be formed. The channel hole can extend through the word line layers and the insulating layers in the vertical direction. The channel hole can include trenches that extend away from the first vertical axis and are concentrically arranged along the first vertical axis. The channel hole can further include sidewalls and a bottom to extend into the substrate. A barrier layer can subsequently be formed along the sidewalls of the channel hole, where the barrier layer can be in contact with the word line layers and the insulating layers. A charge trapping layer can be formed over an inner surface of the barrier layer. A tunneling layer can be formed over an inner surface of the charge trapping layer, and a channel layer can be formed over an inner surface of the tunneling layer. The barrier layer, the charge trapping layer, the tunneling layer, and the channel layer can be arranged in the trenches and positioned concentrically around the first vertical axis so as to form the storage structures.

In some embodiments, in order to form the first isolation structure, a circular hole can be formed in the first channel structure, where the circular hole can extend through the word line layers and the insulating layers along the first vertical axis in the vertical direction. The circular hole can subsequently be filled with a dielectric layer to form the first isolation structure so that the storage structures are separated from each other by the first isolation structure.

Further, a cross-section of the first isolation structure can have a circular shape with a radius. The radius can be centered at an interception point between the cross-section of the first channel structure and the first vertical axis. The radius can be equal to R that is in a range of 20 nm to 50 nm.

In some embodiments, a cross-section of a first storage structure of the storage structures can include a top side and two opposing edge sides, where the cross-section of the first storage structure is perpendicular to the first vertical axis. A first distance between the first vertical axis and the top side can be equal to 2R that is in a range of 70 nm to 100 nm. A second distance between the two opposing edge sides can be equal to \sqrt{3} R that is in a range of 50 nm to 80 nm.

In the method, a second channel structure can further be formed that extends along a second vertical axis in the vertical direction through the word line layers and the insulating layers. The second channel structure can include a plurality of storage structures that extend away from the second vertical axis and are arranged concentrically along the second vertical axis. A second isolation structure can be arranged in the second channel structure so as to extend along the second vertical axis and separate the storage structures of the second channel structure from one another. The second channel structure can be disposed at a first side of the first channel structure and have an opposing orientation to an orientation of the first channel structure. A space between the first channel structure and the second channel structure can be in a range of 40 nm to 60 nm.

In the method, a third channel structure can be formed that extends along a third vertical axis in the vertical direction through the word line layers and the insulating layers. The third channel structure can include a plurality of storage structures that extend away from the third vertical axis and are arranged concentrically along the third vertical axis. A third isolation structure can be positioned in the third channel structure so as to extend along the third vertical axis and separate the three storage structures of the third channel structure from one another. The third channel structure can be positioned at a second side of the first channel structure and have a same orientation to the orientation of the first channel structure. A space between the first channel structure and the third channel structure can be in a range of 50 nm to 70 nm.

According to yet another aspect of the disclosure, a semiconductor device is provided. The semiconductor device can include an array region and a staircase region that are positioned adjacent each other. The array region and the staircase region can be formed in a stack of alternating word line layers and insulating layers that is positioned over a substrate of the semiconductor device in a vertical direction. A channel structure can be formed in the stack. The channel structure can extend along a vertical axis in the vertical direction through the word line layers and the insulating layers, and include a plurality of storage structures and an isolation structure. Word line contacts can be formed in the staircase region, where the word line contacts can extend from the word line layers of the staircase region along the vertical direction. The storage structures of the channel structure can be arranged around the isolation structure. The isolation structure of the first channel structure can extend along the vertical axis and separate the storage structures from one another.

A first storage structure of the storage structures can include a barrier layer, a charge trapping layer, a tunneling layer, and a channel layer that are concentrically arranged in the channel structure along the vertical axis. The barrier layer can be formed along the vertical direction and in contact with the word line layers and the insulating layers. The charge trapping layer can be formed over an inner surface of the barrier layer and extend in the vertical direction. The tunneling layer can be formed over an inner surface of the charge trapping layer and extend in the vertical direction. The channel layer can be formed over an inner surface of the tunneling layer and extend in the vertical direction.

In some embodiments, the storage structures can include three storage structures that are equally spaced apart from one another around the first isolation structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is cross-sectional view of an exemplary 3D-NAND device, in accordance with exemplary embodiments of the disclosure.

FIG. 2 is a top-down view of an exemplary channel structure, in accordance with exemplary embodiments of the disclosure.

FIG. 3 is a cross-sectional view of exemplary channel structure, in accordance with exemplary embodiments of the disclosure.

FIGS. 4A, 4B, and 4C are top-down views of various intermediate steps of manufacturing a channel structure, in accordance with exemplary embodiments of the disclosure.

FIG. 5 is a top-down view of a first exemplary layout of channel structures, in accordance with exemplary embodiments of the disclosure.

FIG. 6 is a top-down view of a second exemplary layout of channel structures, in accordance with exemplary embodiments of the disclosure.

FIG. 7 is a flowchart of a process for manufacturing a 3D-NAND device, in accordance with exemplary embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A 3D-NAND device can staircase regions and array regions that are formed in a stack of word line layers and insulating layers. The word line layers and the insulating layers can be disposed alternatingly over a substrate. The word line layers can include bottom select gate (BSG) layers, gate layers (or word line layers), and top select gate (TSG) layers that are disposed sequentially over the substrate. The array regions can include a plurality of channel structures. Each of the channel structures can be coupled to the word line layers to form a respective vertical NAND memory cell string. The vertical NAND memory cell string can include one or more bottom select transistors (BSTs), a plurality of memory cells (MCs), and one or more top select transistors (TSTs) that are disposed sequentially and in series over the substrate along a height direction (or Z direction) of the substrate. The BSTs can be formed of the channel structure and the BSG layers, the MCs can be formed of the channel structure and the word line layers, and the TSTs can be formed of the channel structure and the TSG layers.

In such a 3D-NAND device, the staircase regions can include stairs that can be formed in the BSG layers, the word line layers, and the TSG layers. Word line contacts can further be formed on the stairs to connect to the BSG layers, the word line layers, and the TSG layers. In a related example, a channel structure can be formed through a channel hole with multiple layers of material concentrically arranged, for example, circularly about a central axis. The channel hole can be a concentric circle, and the multiple layers can include a barrier layer (e.g., SiO layer), a charge trapping layer (e.g., SiN layer), a tunneling layer (e.g., SiO layer) and a channel layer (e.g., a poly Si layer) that are sequentially filled in the concentric circle. In addition, the concentric circle can be filled with an insolation layer (e.g., SiO layer) so as to form a continuous charge capture memory structure from a top to a bottom of the channel structure. The advantage of forming such a channel structure is that the storage density can be maximized by increasing the density of concentric circles and the number of stacking layers at the minimum cost. However, as the bit density of the 3D-NAND memory device increases, the alignment issue of the channel holes in different stacks (e.g., an upper stack and a lower stack) or the connection issue of the channel holes based on a double pattern is getting worse.

In the disclosure, the bit density of the 3D-NAND can be improved based on split gates (or split cells). The split cells can be formed by splitting a channel structure into multiple channel sections that are separated from one another. Thus, a single memory cell string can be split into multiple memory cell strings. In order to split a channel structure into channel sections, the channel structure can be formed to have a cross-section including multiple leg structures (or storage structures), such as a Y-shaped cross-section including three leg structures. An isolation structure can subsequently be arranged in the channel structure so that the leg structures are spaced apart from one another by the isolation structure. Accordingly, a corresponding memory cell string can be formed based on each of the leg structures, and the bit density can be increased by 84%, for example, comparing to a related 3D-NAND device.

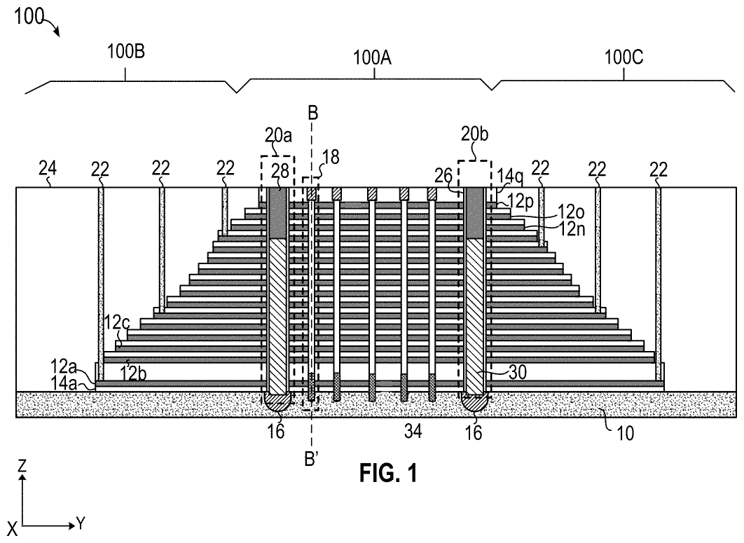

FIG. 1 is a cross-sectional view of an exemplary 3D-NAND memory device 100 (also referred to as device 100). As shown in FIG. 1, the 3D-NAND memory device 100 can have a substrate 10. A plurality of word line layers 12 and a plurality of insulating layers 14 are stacked alternatingly over the substrate 10. In an exemplary embodiment of FIG. 1, sixteen word line layers and seventeen insulating layers are included. However, FIG. 1 is merely an example, and any number of word line layers and insulating layers can be included based on the device structure.

In some embodiments, a lowermost word line layer 12a can function as a bottom select gate (BSG) layer that is connected to a gate of a BST. In some embodiments, one or more of the word line layers over the BSG layer 12a, such as word line layer 12b-12c, can be dummy word line layers (or dummy BSG layers) that are connected to gates of dummy memory cells (dummy MCs). The BST and the dummy MCs together can control data transmission between array common source (ACS) regions 16 and the memory cells.

In some embodiments, an uppermost word line layer 12p can function as a top select gate (TSG) layer that is connected to a gate of a TST. One or more of the word line layers under the TSG layer 12p, such as word line layers 12n-12o, can be dummy word line layers (or dummy TSG layers) that are connected to gates of dummy memory cells (dummy MCs). The TST and the dummy MCs together control data transmission between bit lines (not shown) and the memory cells.

The insulating layers 14 can be positioned on the substrate 10 and arranged with the word line layers 12 alternatingly. The word line layers 12 are spaced part from one another by the insulating layers 14. In addition, the word line layers 12 can be separated from the substrate 10 by a lowermost insulating layer 14a of the insulating layers 14.

In some embodiments, the word line layers 12 illustrated in FIG. 1 are formed first using sacrificial word line layers (e.g., SiN). The sacrificial word line layers can be removed and replaced with a high K layer, glue layers, and one or more metal layers. The high K layer can be made of aluminum oxide (Al₂O₃) and/or Hafnium oxide (HfO₂) and/or Tantalum oxide (Ta₂O₅), and/or another material of high K (Dielectric Constant). The metal layer can be made of tungsten (W), Cobalt (Co), for example. The word line layers 12 can have a thickness in a range from 10 nm to 100 nm, according to requirements of product specification, device operation, manufacturing capabilities, and so on. In an embodiment of FIG. 1, the insulating layers can be made of SiO₂ with a thickness from 5 nm to 50 nm.

In some embodiments, the 3D-NAND memory device 100 can have an array region 100A and two staircase regions 100B-100C. The staircase regions 100B-100C can be positioned at two sides of the array region 100A. The word line layers and the insulating layers can extend into the staircase region 100B-100C with a stair-cased profile or step-cased profile.

As shown, the 3D-NAND memory device 100 can also include a plurality of channel structures 18 in the array region 100A. The channel structures 18 are formed over the substrate 10 along a Z-direction (also referred to as vertical direction or height direction) of the substrate. As shown in FIG. 1, five channel structures 18 are included. However, FIG. 1 is merely an example, and any number of channel structures 18 can be included in the 3D-NAND memory device 100. The channel structures 18 can extend through the word line layers 12 and the insulating layers 14, and further extend into the substrate 10 to form an array of vertical memory cell strings.

Each of the vertical memory cell strings can include a corresponding channel structure that is coupled to the word line layers 12 to form one or more bottom select transistors (BSTs), a plurality of memory cells (MCs), and one or more top select transistors (TSTs). The BSTs, MCs, and TSTs are disposed sequentially and in series over the substrate. In addition, each of the channel structures 18 can further include a channel layer, a tunneling layer, a charge trapping layer, and a barrier layer that are concentrically arranged around and extend along a vertical axis B-B′.

The 3D-NAND memory device 100 can have a plurality of slit structures (or gate line slit structures). For example, two slit structures 20a-20b are included in FIG. 1. In some embodiments, a gate-last fabrication technology is used to form the 3D-NAND memory device 100, thus the slit structures are formed to assist in the removal of the sacrificial word line layers, and the formation of the real gates. In some embodiments, the slit structures can be made of conductive materials and positioned on array common source (ACS) regions 16 to serve as contacts, where the ACS regions are formed in the substrate 10 to serve as common sources. In some embodiments, the slit structures can be made of dielectric materials to serve as separation structures. In an exemplary embodiment of FIG. 1, the slit structures 20a-20b are positioned at two opposing boundaries of the array region 100A and connected to the ACS regions 16.

In some embodiments, the slit structures 20a-20b can extend through the word line layers 12 and the insulating layers 14, and further extend along a first direction (also referred to as a length direction, or a X direction) of the substrate 10. In some embodiments, the slit structures 20a-20b can have a dielectric spacer 26, a conductive layer 30, and a contact 28. The dielectric spacer 26 is formed along sidewalls of the slit statures and in contact with the word line layers and the insulating layers. The conductive layer 30 is formed along the dielectric spacer 26 and over the ACS regions 16. The contact 28 is formed along the dielectric spacer 26 and over the conductive layer 30. In an embodiment of FIG. 1, the dielectric spacer 26 is made of SiO₂, the conductive layer 30 is made of polysilicon, and the contact 28 is made of tungsten.

The 3D-NAND memory device 100 can have a plurality of word line contact structures 22. The word line contact structures 22 are formed in a dielectric layer 24 and positioned on the word line layers 12 to connect to the word line layers 12. For simplicity and clarity, only three word line contact structures 22 are illustrated in each of the staircase regions 100B and 100C. The word line contact structures 22 can further be coupled to gate voltages. The gate voltages can be applied to gates of the BSTs, the MCs, and the TSTs through the word line layers to operate the BSTs, the MCs, and the TSTs correspondingly.

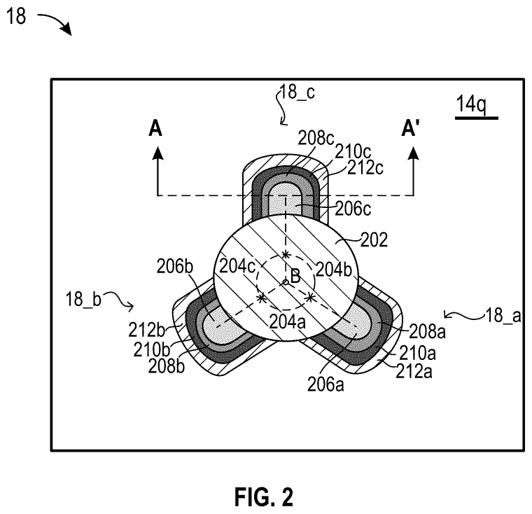

FIG. 2 is a top-down view of a first exemplary channel structure 18, in accordance with exemplary embodiments of the disclosure. As shown in FIG. 2, the channel structure 18 can include a plurality of leg structures (or storage structures) and an isolation structure. The leg structures can be arranged around the isolation structure. The isolation structure can extend along a vertical axis (e.g., B-B′) and separate the leg structures from one another. In an exemplary embodiment of FIG. 2, the channel structure 18 can include three leg structures (or storage structures) 18_a, 18_b, and 18_c and an isolation structure 202. Of course, FIG. 2 is merely an example, and the channel structure 18 can include any number of leg structures according to the designs. In some embodiment, the leg structures can be equally spaced apart from one another around the isolation structure. In other embodiments, the leg structures can be unequally spaced apart from one another around the isolation structure.

Still referring to FIG. 2, when the channel structure 18 includes three leg structures (or storage structures) 18_a, 18_b, and 18_c, the channel structure 18 can have a Y-shaped cross-section that is perpendicular to the vertical axis B-B′, where the three leg structures 18_a, 18_b, and 18_c are arranged around the isolation structure 202. The channel structure 18 can also include a barrier layer 212, a charge trapping layer 210, a tunneling layer 208, and a channel layer 206 that are concentrically arranged along the vertical axis B-B′ in the three leg structures 18_a, 18_b, and 18_c. As shown in FIG. 2, the barrier layer 212 can be formed along the vertical direction (or Z-direction) and in contact with the word line layers 12 and the insulating layers 14. The charge trapping layer 210 can be formed over an inner surface of the barrier layer 212 and extend in the vertical direction. The tunneling layer 208 can be formed over an inner surface of the charge trapping layer 210 and extend in the vertical direction, and the channel layer 206 can be formed over an inner surface of the tunneling layer 208 and extend in the vertical direction.

Still referring to FIG. 2, an isolation structure 202 can be positioned in the channel structure 18 so as to extend along the vertical axis B-B′ and separate the three leg structures 18_a, 18_b, and 18_c from one another in the Y-shaped cross-section of the channel structure 18. Accordingly, the barrier layer 212 can be separated into barrier layer sections 212a, 212b and 212c that are disposed in the leg structures 18_a, 18_b and 18_c, respectively. Similarly, the charge trapping layer 210 can be separated into charge trapping layer sections 210a, 210b, and 210c that are disposed in the leg structures 18_a, 18_b and 18_c, respectively. The tunneling layer 208 can be separated into tunneling layer sections 208a, 208b and 208c that are disposed in the leg structures 18_a, 18_b and 18_c, respectively. The channel layer 206 can be separated into channel layer section 206a, 206b and 206c that are disposed in the leg structures 18_a, 18_b and 18_c, respectively.

In some embodiments, the isolation structure 202 can have a circular cross-section that is perpendicular to the vertical axis B-B′. The isolation structure 202, the barrier layer 212, the charge trapping layer 210, the tunneling layer 208, and the channel layer 206 can be concentrically arranged along the vertical axis B-B. Further, the isolation structure 202 can be made of a dielectric material, such as SiO, SiN, SiCN, or other suitable dielectric materials.

In some embodiments, the three leg structures 18_a, 18_b and 18_c can be equally distributed along the vertical axis B-B′ in the cross-section of the channel structure 18. Thus, a first angular distance 204a between the first leg structure 18_a and the second leg structure 18_b in the cross-section of the channel structure 18, a second angular distance 204b between the first leg structure 18_a and the third leg structure 18_c in the cross-section of the channel structure 18, and a third angular distance 204c between the second leg structure 18_b and the third leg structure 18_c in the cross-section of the channel structure 18 can be equal. In some embodiments, the three leg structures 18_a, 18_c and 18_c can be unevenly distributed along the vertical axis B-B′. Thus, the first angular distance 204a, the second angular distance 204b, and the third angular distance 204c are different.

The channel structure 18 in FIG. 2 illustrates a tri-phase split cell configuration, where three separate memory cell strings can be formed based on the three leg structures 18_a, 18_c and 18_c, and the word line layers 12. For example, a first memory cell string can be formed based on the first leg structure 18_a that includes the barrier layer section 212a, the charge trapping layer section 210a, and the tunneling layer section 208a, and the channel layer section 206a. A second memory cell can be formed based on the second leg structure 18_b that includes the barrier layer section 212b, the charge trapping layer section 210b, and tunneling layer section 208b, and the channel layer section 206b. A third memory cell string can be formed based on the third leg structure 18_c that includes the barrier layer section 212c, the charge trapping layer section 210c, and the tunneling layer section 208c, and the channel layer section 206c. Comparing to the bit density in a related 3D-NAND device, the bit density of the device 100 can be tripled.

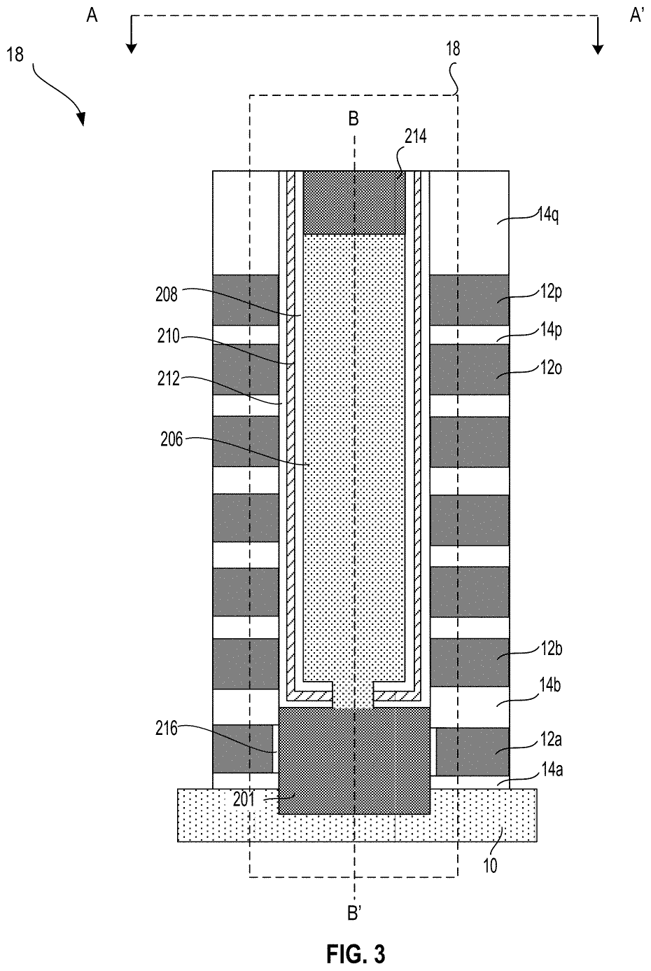

FIG. 3 is a cross-sectional view of an exemplary channel structure 18. The cross-sectional view of the channel structure in FIG. 3 is obtained from a plane same as the vertical plane containing line A-A′ in FIG. 2. As shown in FIG. 3, the channel structure 18 can have a cylindrical shape with sidewalls and a bottom region. Of course, other shapes are possible. The channel structure 18 is formed along the Z-direction (or vertical direction) perpendicular to the substrate 10, and electrically coupled with the substrate 10 via a bottom channel contact 201 that is positioned at the bottom region of the channel structure. The channel structure 18 further includes a channel layer 206, a tunneling layer 208, a charge trapping layer 210, and a barrier layer 212. The barrier layer 212 is formed along the sidewalls of the channel structure 18 and over the bottom channel contact 201. The barrier layer 212 is in contact with the word line layers 12 and the insulating layers 14. The charge trapping layer 210 is formed along the barrier layer 212 and over the bottom channel contact 201, and the tunneling layer 208 is formed along the charge trapping layer 210 and over the bottom channel contact 201.

The channel layer 206 can be formed along the tunneling layer 208 and further extend through bottom portions of the tunneling layer 208, the charge trapping layer 210, and the barrier layer 212 so as to be in contact with the bottom channel contact 201, where the bottom portions of the tunneling layer 208, the charge trapping layer 210, and the barrier layer 212 are positioned over the bottom channel contact 201. Thus, the channel layer 206 can have a T-shaped profile that is illustrated in cross-sectional view of FIG. 3. In addition, the tunneling layer 208, the charge trapping layer 210, and the barrier layer 212 can form an “L-foot” configuration in the channel structure 18. The L-foot configuration can include side portions that are formed along the sidewalls of the channel structure 18 and a bottom portion over the bottom channel contact 201.

The channel structure 18 can further include a top channel contact 214 that is formed along the tunneling layer 208 and positioned over the channel layer 206. The top channel contact 214 is positioned above the TSG layer 12p to prevent any electrical interference between the top channel contact 214 and the TSG layer 12p. For simplicity and clarity, the top channel contact 214 is not illustrated in FIG. 2. In some embodiments, the channel structure 18 can include a gate dielectric layer 216 that is formed between the BSG layer 12a and the bottom channel contact 201. The gate dielectric layer 216 can be positioned between the insulating layer 14b and 14a, and have an annular shape to surround the bottom channel contact 201.

In an embodiment of FIG. 3, the barrier layer 212 is made of SiO₂. In another embodiment, the barrier layer 212 can include multiple layers, such as SiO₂ and Al₂O₃. In an embodiment of FIG. 3, the charge trapping layer 210 is made of SiN. In another embodiment, the charge trapping layer 210 can include a multi-layer configuration, such as a SiN/SiON/SiN multi-layer configuration. In some embodiments, the tunneling layer 208 can include a multi-layer configuration, such as a SiO/SiON/SiO multi-layer configuration. In an embodiment of FIG. 3, the channel layer 206 is made of polysilicon via a furnace low pressure chemical vapor deposition (CVD) process. The top and bottom channel contacts 214 and 201 can be made of polysilicon.

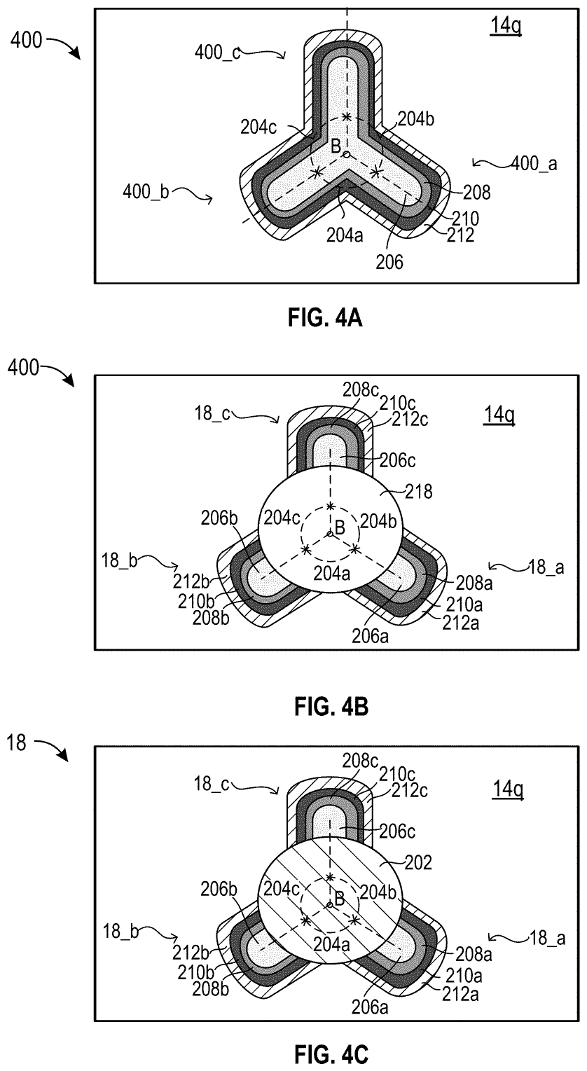

FIGS. 4A, 4B, and 4C are top-down views showing cross-sections of various intermediate steps of manufacturing a channel structure, in accordance with exemplary embodiments of the disclosure. As shown in FIG. 4A, a pre-channel structure 400 can be formed in the word line layers 12 and the insulating layers 14. The pre-channel structure 400 can have a Y-shaped cross-section that is perpendicular to the vertical axis B-B′, and include three leg structures (or storage structures) 400_a, 400_b, and 400_c that extend away from the vertical axis B-B′ in the vertical direction (Z-direction). In some embodiments, the three leg structures 400_a, 400_b, and 400_c can be evenly distributed around the vertical axis B-B′ in the cross-section of the per-channel structure 400. Thus, a first angular distance 204a between the first leg structure 400_a and the second leg structure 400_b in the cross-section of the pre-channel structure 400, a second angular distance 204b between the first leg structure 400_a and the third leg structure 400_c in the cross-section of the pre-channel structure 400, and a third angular distance 204c between the second leg structure 400_b and the third leg structure 400_c in the cross-section of the pre-channel structure 400 are equal.

Still referring to FIG. 4A, the pre-channel structure 400 can have a barrier layer 212, a charge trapping layer 210, a tunneling layer 208, a channel layer 206 that are concentrically arranged along the vertical axis B-B′. The barrier layer 212 is formed in the vertical direction and in contact with the word line layers 12 and the insulating layers 14. The charge trapping layer 210 is formed over an inner surface of the barrier layer 212 and extends in the vertical direction. The tunneling layer 208 is formed over an inner surface of the charge trapping layer 210 and extends in the vertical direction. The channel layer 206 is formed over an inner surface of the tunneling layer 208 and extends in the vertical direction. Cross-sections of the barrier layer 212, the charge trapping layer 210, the tunneling layer 208, and the channel layer 206 can be Y-shaped and have a closed-loop configuration.

In order to form the pre-channel structure 400, a channel hole (not shown) can be formed through a patterning process that can include a photolithographic process and an etching process. The channel hole can extend through the word line layers 12 and the insulating layers 14 in the vertical direction. The channel hole can have a Y-shaped cross-section that is perpendicular to the vertical axis B-B′ and include three trenches (not shown) that extend away from the vertical axis B-B′. The channel hole can further include sidewalls and a bottom to extend into the substrate 10. The barrier layer 212 can be subsequently deposited along the sidewalls of the channel hole, where the barrier layer can be in contact with the word line layers and the insulating layers. The charge trapping layer 210 can be formed over the inner surface of the barrier layer 212. The tunneling layer 208 can be formed over the inner surface of the charge trapping layer 210, and a channel layer 206 can be formed over the inner surface of the tunneling layer 208. Any suitable deposition techniques can be applied to form the barrier layer, the charge trapping layer, the tunneling layer, and the channel layer, such as a chemical vapor deposition (CVD) process, a physical vapor deposition (PVD) process, a diffusion process, an atomic layer deposition (ALD) process, a sputtering process, or a combination thereof.

In FIG. 4B, an isolation hole 218 can be formed in the pre-channel structure 400, where the isolation hole can extend through the word line layers 12 and the insulating layers 14 along the vertical axis B-B′ in the vertical direction. In some embodiments, the isolation hole can have a circular cross-section or an oval cross-section that is perpendicular to the vertical axis B-B′. In order to form the isolation hole, a patterned photoresist mask can be formed on the pre-channel structure 400 to uncover a circular area along the vertical axis B-B′. An etching process, such as a wet etching process or a dry plasma etching process, can subsequently be applied to remove portions of the pre-channel structure 400, and portions of the word line layers 12 and the insulation layers 14 in the circular area so as to form the isolation hole. When the isolation hole is formed, portions of the leg structures 400_a, 400_b, and 400_c that are covered by the photoresist mask can remain, and become the leg structures 18_a, 18_b, and 18_c respectively.

In FIG. 4C, a dielectric layer can be deposited into the isolation hole to form the isolation structure 202. In some embodiments, the dielectric layer can include SiO, SiN, SiCN, or other suitable dielectric materials. The dielectric layer can be deposited through a CVD process, a PVD process, a diffusion process, an ALD process, or any other suitable deposition process. In some embodiments, a surface planarization process, such as a chemical-mechanic polishing (CMP), can be applied to remove any excessive dielectric layer. When the isolation structure 202 is formed, a channel structure 18 can be formed. The channel structure 18 can have similar configurations to the channel structure 18 in FIG. 2. For example, the channel structure 18 in FIG. 4C can have a Y-shaped cross-section that includes three leg structures 18_a, 18_b, and 18_c. The three leg structures 18_a, 18_b, and 18_c are spaced apart from one another by the isolation structure 202. The three leg structures 18_a, 18_b, and 18_c can be evenly distributed along the vertical axis B-B′, where the angular distances 204a-204c are equal.

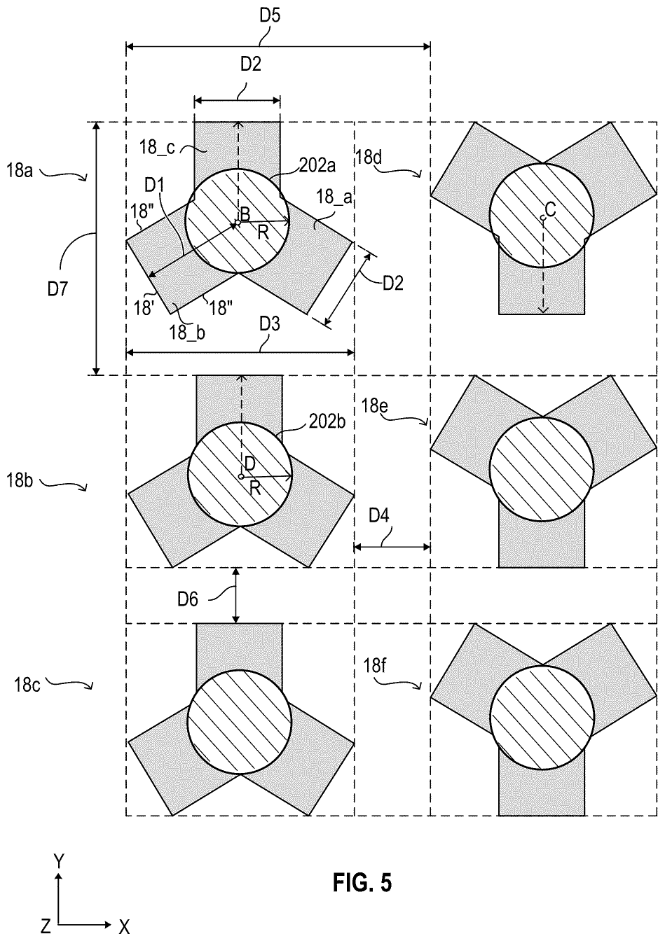

FIG. 5 is a top-down view showing a cross-section of a first exemplary layout of channel structures, in accordance with exemplary embodiments of the disclosure. As shown in FIG. 5, a plurality of channel structures 18 can be formed in the word line layers 12 and insulating layer 14. In an exemplary embodiment of FIG. 5, the channel structures 18 can have three leg structures (or storage structures) with a Y-shaped cross-section. Of course, FIG. 5 is merely an example, and the channel structures 18 can include any number of leg structures. The channel structures 18 can extend through the word line layers 12 and insulating layer 14 along the vertical direction. In an exemplary embodiment of FIG. 5, six channel structures 18a-18f are included. The channel structures 18 can be aligned along one or more directions (or orientations). For example, channel structures 18a-18c can be aligned along the Y direction and channel structures 18d-18f can be aligned along the −Y direction. In some embodiments, cross-sections of the isolation structures that are arranged along vertical axes can have a radius that is equal to R. The R can be in a range of 20 nm to 50 nm. For example, the isolation structure 202a that is arranged along the vertical axis B-B′ can have a cross-section with a radius that is equal to R. Similarly, the isolation structure 202b that is arranged along a vertical axis D-D′ can have a cross-section with a radius equal to R. In some embodiments, cross-sections of the leg structures of the channel structures can have a top side and two opposing edge sides. For example, the cross-section of leg structure 18_b of the channel structure 18a that is perpendicular to the vertical axis B-B′ can have a top side 18′ and two opposing edge sides 18″. A first distance D1 between the vertical axis B-B′ and the top side 18′ can be equal to 2R that is in a range of 70 nm to 100 nm. A second distance D2 between the two opposing edge sides 18″ can be equal to \sqrt{3} R that is in a range of 50 nm to 80 nm. Further, a critical dimension (CD) D3 of the Y-shaped cross-section of the channel structure 18a can be equal to

$$5 \frac{\sqrt{3}}{2} R$$

that is in a range of 130 nm to 170 nm.

Still referring to FIG. 5, a channel structure and an adjacent channel structure of the channel structure that have different orientations and are positioned in a same row can have a space distance D4 and a pitch distance D5. For example, the channel structure 18a and the channel structure 18d can have a space distance D4 that is in a range of 40 nm to 60 nm, and a pitch distance D5 that is in a range of 180 nm and 220 nm. In addition, a channel structure and an adjacent channel structure of the channel structure that have a same orientation and are positioned in a same column can have a space distance D6 and a pitch distance D7. For example, the channel structure 18a and the channel structure 18b can have a space distance D6 that is in a range of 50 nm and 70 nm, and a pitch distance D7 that is in a range of 150 nm and 190 nm.

It should be noted that FIG. 5 is merely an example, and the channel structures 18a-18f can be arranged in a number of orientations. For example, the channel structure 18a and the channel structure 18d can be arranged with respect to one another in any angle. In another embodiment, the channel structure 18a and the channel structure 18d can be overlapped so that a less space of the 3D-NAND device can be occupied and a cell density can be increased accordingly.

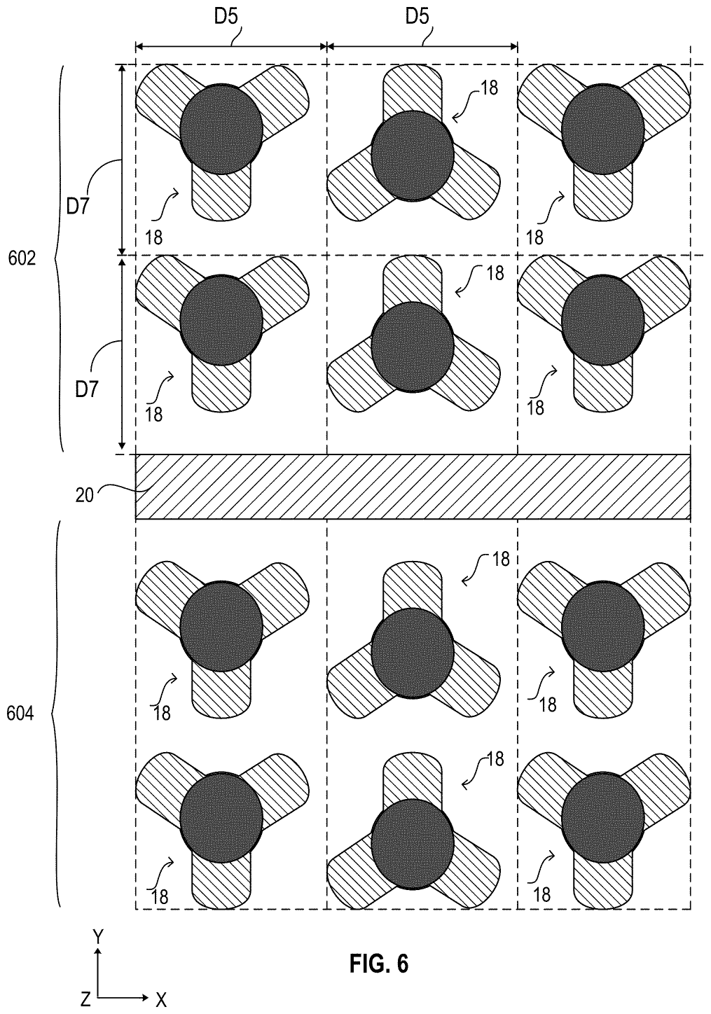

FIG. 6 is a top-down view showing a cross-section of a second exemplary layout of channel structures, in accordance with exemplary embodiments of the disclosure. As shown in FIG. 6, a plurality of channel structures 18 can be formed in the word line layers 12 and insulating layers 14 and extend along the vertical direction (or Z-direction). The channel structures 18 in a same row can have a pitch distance D5, and the channel structures 18 in a same column can have a pitch distance D7. The channel structures 18 can be separated into a first group 602 and a second group 604 by a slit structure 20. The slit structure 20 can be the slit structure 20 shown in FIG. 1. The slit structure 20 extends into the word line layers 12 and insulating layers 14 and further extends along the X direction. In some embodiment, the first group 602 and the second group 604 can be included in a same memory block. Thus, the first group 602 can be included in a first finger region and the second group 604 can be included in a second finger region of the memory block. In some embodiments, the first group 602 and the second group 604 can be included in different memory blocks. For example, the first group 602 is included in a first memory block, and the second group 604 can be included in a second memory block.

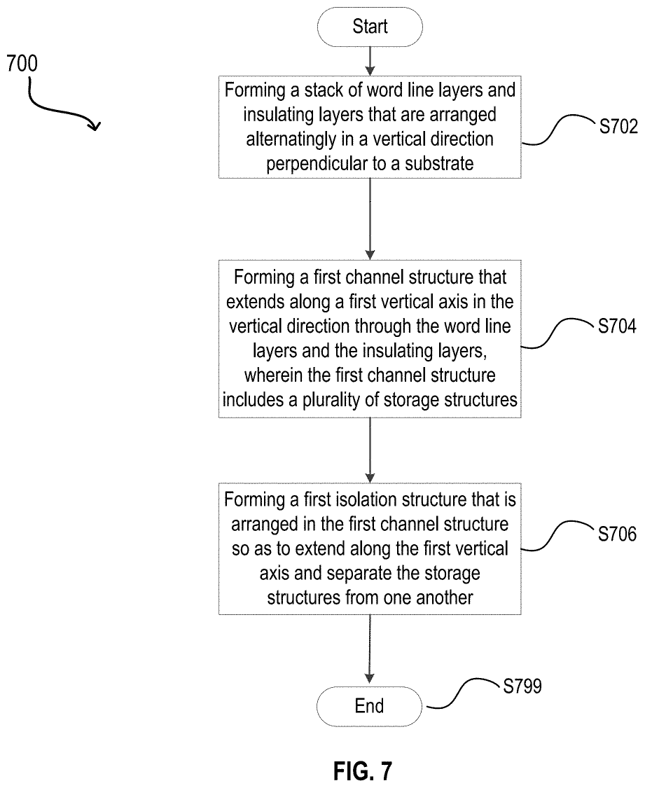

FIG. 7 is a flowchart of a process 700 for manufacturing the disclosed 3D-NAND device in accordance with some embodiments of the present disclosure. The process 700 begins at step S702 where word line layers and insulating layers are formed. The word lien layers and insulating layers can be alternatingly stacked along a vertical direction perpendicular to a substrate of the semiconductor device. In some embodiments, the process 700 can have a gate-first fabrication technology, where the word line layers can be formed before the channel structures are formed. Accordingly, at step S702, the word line layers can be formed and can include polysilicon and/or WSiₓ. In some embodiments, the process 700 can have a gate-last fabrication technology, where the word line layers are formed after the channel structures are formed. Thus, at step S702, sacrificial layers instead of word line layers can be formed. The sacrificial layers can be dielectric layers, such as SiN layers. In some embodiments, the steps S702 can be performed as illustrated with reference to FIG. 1.

At step S704, a first channel structure can be formed. The first channel structure can extend along a first vertical axis in the vertical direction through the word line layers and the insulating layers. The first channel structure can include a plurality of storage structures that extend away from the first vertical axis and arranged concentrically along the first vertical axis. In addition, when the process 700 has the gate-last fabrication technology, the sacrificial layers formed at step S702 can be replaced with conductive layers to form the word line layers. The conductive layers can include conductive materials, such as tungsten, and high-K materials, such as AlO, HfO, and TaO. In some embodiments, the steps S704 can be performed as illustrated with reference to FIG. 4A.

The process 700 then proceeds to step S706. At step S706, a first isolation structure can be formed. The first isolation structure can be arranged in the first channel structure so as to extend along the first vertical axis and separate the storage structures from one another. In some embodiments, the steps S706 can be performed as illustrated with reference to FIGS. 4B and 4C.

It should be noted that additional steps can be provided before, during, and after the process 700, and some of the steps described can be replaced, eliminated, or performed in different order for additional embodiments of the process 700. For example, one or more channel structures can be formed concurrently with the first channel structure. In addition, word line contacts in the staircase regions, and gate line split structures (or slit structures) in the array region can also be formed. Moreover, various additional interconnect structures (e.g., metallization layers having conductive lines and/or vias) may be formed over the first and second contact structures of the 3D-NAND device. Such interconnect structures electrically connect the 3D-NAND device with other contact structures and/or active devices to form functional circuits. Additional device features such as passivation layers, input/output structures, and the like may also be formed.

The various embodiments described herein offer several advantages over related 3D-NAND devices. For example, in the related 3D-NAND devices, as the bit density of the 3D-NAND memory device increases, the alignment issue of the channel holes in different stacks (e.g., an upper stack and a lower stack) or the connection issue of the high dense channel holes formed by a double pattern is getting worse. In the disclosure, the bit density of the 3D-NAND can be improved based on split gates (or split cells). The split cells can be formed by splitting a channel structure into multiple channel sections (e.g., storage structures) that are separated from one another. Thus, a single memory cell string can be split into multiple memory cell strings. Accordingly, the issues experienced in the related 3D-NAND devices can be avoided.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a stack of word line layers and insulating layers that are alternatingly arranged along a vertical direction perpendicular to a substrate of the semiconductor device; and
a first channel structure that extends along a first vertical axis in the vertical direction through the word line layers and the insulating layers and includes a plurality of storage structures and a first isolation structure, wherein:
the storage structures are arranged around the first isolation structure, and
the first isolation structure separates the storage structures from one another.

2. The semiconductor device of claim 1, wherein a cross-section of the first isolation structure that is perpendicular to the first vertical axis has one of a circular profile or an oval profile.

3. The semiconductor device of claim 1, wherein a first storage structure of the storage structures comprises a barrier layer, a charge trapping layer, a tunneling layer, and a channel layer that are concentrically arranged along the first vertical axis in the first channel structure.

4. The semiconductor device of claim 3, wherein:
the barrier layer is formed along the vertical direction and in contact with the word line layers and the insulating layers,
the charge trapping layer is formed over an inner surface of the barrier layer and extends in the vertical direction,
the tunneling layer is formed over an inner surface of the charge trapping layer and extends in the vertical direction, and
the channel layer is formed over an inner surface of the tunneling layer and extends in the vertical direction.

5. The semiconductor device of claim 1, wherein a cross-section of the first isolation structure has a circular shape with a radius equal to R, the radius being centered at an interception point between the cross-section of the first isolation structure and the first vertical axis, the R being in a range of 20 nm to 50 nm.

6. The semiconductor device of claim 5, wherein the storage structures comprise three storage structures that are equally spaced apart from on another around the first isolation structure.

7. The semiconductor device of claim 1, wherein the storage structures comprise three storage structures that are unequally spaced apart from on another around the first isolation structure.

8. The semiconductor device of claim 6, wherein:
a cross-section of a first storage structure of the three storage structures that is perpendicular to the first vertical axis includes a top side and two opposing edge sides,
a first distance between the first vertical axis and the top side is equal to 2R that is in a range of 70 nm to 100 nm,
a second distance between the two opposing edge sides is equal to \sqrt{3} R that is in a range of 50 nm to 80 nm, and
a critical dimension of the cross-section of the first channel structure is equal to 5\sqrt{3}/2R that is in a range of 130 nm to 170 nm.

9. The semiconductor device of claim 1, further comprising a second channel structure that includes a plurality of storage structures and a second isolation structure, wherein:
the second channel structure extend along a second vertical axis in the vertical direction,
the storage structures of the second channel structure are arranged around the second isolation structure,
the second isolation structure separates the storage structures of the second channel structure from one another,
the second channel structure is positioned at a first side of the first channel structure and have an opposing orientation to an orientation of the first channel structure, and
a space between the first channel structure and the second channel structure is in a range of 40 nm to 60 nm.

10. The semiconductor device of claim 9, further comprising a third channel structure that includes a plurality of storage structures and a third isolation structure, wherein:
the third channel structure extend along a third vertical axis in the vertical direction,
the storage structures of the third channel structure are arranged around the third isolation structure,
the third isolation structure separates the storage structures of the third channel structure from one another,
the third channel structure is positioned at a second side of the first channel structure and have a same orientation to the orientation of the first channel structure, and
a space between the first channel structure and the third channel structure is in a range of 50 nm to 70 nm.

11. A method for forming a semiconductor, comprising:
forming a stack of word line layers and insulating layers that are arranged alternatingly in a vertical direction perpendicular to a substrate; and
forming a first channel structure that extends along a first vertical axis in the vertical direction through the word line layers and the insulating layers, wherein the first channel structure includes a plurality of storage structures that extend away from the first vertical axis and are arranged concentrically along the first vertical axis; and
forming a first isolation structure that is arranged in the first channel structure so as to extend along the first vertical axis and separate the storage structures from one another.

12. The method of claim 11, wherein the forming the first channel structure further comprises:
forming a channel hole extending through the word line layers and the insulating layers in the vertical direction, wherein the channel hole includes trenches that extend away from the first vertical axis and are concentrically arranged along the first vertical axis, and the channel hole includes sidewalls and a bottom to extend into the substrate;
forming a barrier layer along the sidewalls of the channel hole, the barrier layer being in contact with the word line layers and the insulating layers;
forming a charge trapping layer over an inner surface of the barrier layer;
forming a tunneling layer over an inner surface of the charge trapping layer; and
forming a channel layer over an inner surface of the tunneling layer, wherein:
the barrier layer, the charge trapping layer, the tunneling layer and the channel layer are arranged in the trenches and positioned concentrically around the first vertical axis so as to form the storage structures.

13. The method of claim 12, wherein the forming the first isolation structure further comprises:
forming a circular hole in the first channel structure, the circular hole extending through the word line layers and the insulating layers along the first vertical axis in the vertical direction; and
filling the circular hole with a dielectric layer to form the first isolation structure so that the storage structures are separated from each other by the first isolation structure.

14. The method of claim 13, wherein the first isolation structure has a circular cross-section with a radius that is centered at an interception point between the circular cross-section of the first isolation structure and the first vertical axis, the radius being equal to R that is in a range of 20 nm to 50 nm.

15. The method of claim 14, wherein:
a cross-section of a first storage structure of the storage structures that is perpendicular to the first vertical axis includes a top side and two opposing edge sides,
a first distance between the first vertical axis and the top side is equal to 2R that is in a range of 70 nm to 100 nm,
a second distance between the two opposing edge sides is equal to \sqrt{3} R that is in a range of 50 nm to 80 nm, and
a critical dimension of a cross-section of the first channel structure is equal to
$$5 \frac{\sqrt{3}}{2} R$$
that is in a range of 130 nm to 170 nm.

16. The method of claim 15, further comprising:
forming a second channel structure that extends along a second vertical axis in the vertical direction through the word line layers and the insulating layers, wherein:
the second channel structure includes a plurality of storage structures and a second isolation structure,
the storage structures of the second channel structure are arranged around the second isolation structure,
the second isolation structure separates the storage structures of the second channel structure from one another,
the second channel structure is positioned at a first side of the first channel structure and have an opposing orientation to an orientation of the first channel structure, and
a space between the first channel structure and the second channel structure is in a range of 40 nm to 60 nm.

17. The method of claim 16, further comprising:
forming a third channel structure that extends along a third vertical axis in the vertical direction through the word line layers and the insulating layers, wherein:
the third channel structure includes a plurality of storage structures and a third isolation structure,
the storage structures of the third channel structure are arranged around the third isolation structure,
the third isolation structure separates the storage structures of the third channel structure from one another,
the third channel structure is positioned at a second side of the first channel structure and have a same orientation to the orientation of the first channel structure, and
a space between the first channel structure and the third channel structure is in a range of 50 nm to 70 nm.

18. A semiconductor device, comprising:
an array region and a staircase region that are positioned adjacent each other and formed in a stack of alternating word line layers and insulating layers that is positioned over a substrate of the semiconductor device in a vertical direction;
a channel structure that extends along a vertical axis in the vertical direction through the word line layers and the insulating layers and includes a plurality of storage structures and an isolation structure; and
word line contacts formed in the staircase region, the word line contacts extending from the word line layers of the staircase region along the vertical direction, wherein:
the storage structures are arranged around the isolation structure, and
the isolation structure extends along the vertical axis and separate the storage structures from one another.

19. The semiconductor device of claim 18, wherein a first storage structure of the storage structures comprises a barrier layer, a charge trapping layer, a tunneling layer, and a channel layer that are concentrically arranged in the channel structure along the vertical axis, wherein:
the barrier layer is formed along the vertical direction and in contact with the word line layers and the insulating layers,
the charge trapping layer is formed over an inner surface of the barrier layer and extends in the vertical direction,
the tunneling layer is formed over an inner surface of the charge trapping layer and extends in the vertical direction, and
the channel layer is formed over an inner surface of the tunneling layer and extends in the vertical direction.

20. The semiconductor device of claim 18, wherein the storage structures comprises three storage structures that are equally spaced apart from one another around the isolation structure.
